(19) United States
(12) Patent Application Publication
(10) Pub. No.: US 2023/0135677 A1
(43) Pub. Date: May 4, 2023

(54) NANOSTRUCTURE MATERIALS AND FABRICATION METHODS

(71) Applicant: The Johns Hopkins University, Baltimore, MD (US)

(72) Inventors: Lance H. Oh, Highland, MD (US); David B. Shrekenhamer, Bethesda, MD (US); Luke J. Currano, Columbia, MD (US); Christine M. Zgrabik, Columbia, MD (US)

(21) Appl. No.: 17/977,008

(22) Filed: Oct. 31, 2022

Related U.S. Application Data
(60) Provisional application No. 63/274,166, filed on Nov. 1, 2021.

(51) Int. Cl. H01L 21/027; H01L 21/033; H01L 21/321; H01L 21/02

(52) U.S. Cl. CPC H01L 21/0273; H01L 21/0337; H01L 21/32115; H01L 21/0228; H01L 21/0259

(57) ABSTRACT

A fabrication method includes depositing a semiconductor material onto a substrate, applying hard mask layer and a photoresist layer, and performing lithography to form voids in the photoresist layer that form a pattern. Additionally, the method may include patterning the hard mask layer based on the pattern in the photoresist layer and etching the semiconductor material based on the patterned hard mask layer to form a cavity in the semiconductor material, and performing atomic layer deposition to deposit pillar material into the cavity including the sidewalls of the cavity such that the pillar material accumulates inwardly from the sidewalls until the cavity is filled. The method may also include planarizing to remove the hard mask layer and pillar material disposed above a pillar height from a surface of the substrate, and removing the semiconductor material to release a pillar of the pillar material supported by the substrate.

### CROSS-REFERENCE TO RELATED APPLICATIONS

This application claims priority to and the benefit of prior-filed, co-pending U.S. Provisional Application No. 63/274,166 filed on Nov. 1, 2021, the entire content of which is hereby incorporated herein by reference.

### TECHNICAL FIELD

Exemplary embodiments generally relate to materials fabrication, and more specifically, relate to fabrication of nanostructure materials.

### BACKGROUND

Nanostructure materials, which include structures on the nanometer scale, for example, a scale of 1 to 1000 nanometers (nm), have been found to exhibit interesting or unexpected properties relative to bulk material counterparts. For example, nanostructure materials have been found to act upon electromagnetic radiation similar to a lens to focus the radiation and otherwise affect propagation of photons. As a result, new uses for nanostructure materials are currently being researched in a variety of applications. Some of the properties that are exhibited by nanostructure materials are a function of the height and the width of the structures that made up the material. The ratio of the height of these structures to their width may be referred to as the aspect ratio of the structure, which may take the form of a pillar.

Many fabrication processes are used to the form nanostructures and associated nanostructure materials. However, conventional fabrication processes have limitations with respect to the aspect ratios of structures that can be constructed. In some instances, attempts to increase the height of a structure with a given width using conventional fabrication methods results in poor structural integrity and frequent breakage and collapsing of the structures. As such, low or no yield results can be the outcome using conventional fabrication methods. Additionally, conventional fabrication techniques can be limited in the architectures and geometries that can be used when constructing a nanostructure, thereby limiting the properties that can be realized by the materials.

Accordingly, there is a need for improved fabrication processes that can reliably yield high aspect ratio structures for use in forming nanostructure materials. Such high aspect ratio structures would facilitate new applications based on the properties that can be realized by such nanostructure materials having the high aspect ratio structures.

### BRIEF SUMMARY

According to some non-limiting, example embodiments, an example fabrication method is provided. The example method may include depositing a semiconductor material onto a substrate, applying hard mask layer, applying a photoresist layer, and performing lithography to form voids in the photoresist layer that form a pattern. The example method may further include applying the pattern to the hard mask layer based on the pattern in the photoresist layer, etching the semiconductor material based on the pattern in the hard mask layer to form a cavity in the semiconductor material, and performing atomic layer deposition to deposit pillar material into the cavity. The atomic layer deposition may apply the pillar material to sidewalls of the cavity such that the pillar material accumulates inwardly from the sidewalls until the cavity is filled. The example method may further include planarizing to remove the hard mask layer and pillar material disposed above a pillar height from a surface of the substrate, and removing the semiconductor material to release a pillar of the pillar material supported by the substrate.

According to some example embodiments, an example fabrication method for a nanostructure material array is provided. The example method may include depositing a semiconductor material onto a substrate, applying hard mask layer, applying a photoresist layer, and performing lithography to form voids in the photoresist layer that form a pattern. The example method may further include applying the pattern to the hard mask layer based on the pattern in the photoresist layer, and etching the semiconductor material based on the pattern in the hard mask layer to form a plurality of cavities including a first cavity in the semiconductor material and a second cavity in the semiconductor material. The first cavity may have a first cross-sectional dimension that is larger than a largest cross-sectional dimension of the second cavity. The example method may further include performing atomic layer deposition to deposit pillar material into the first cavity and the second cavity. The atomic layer deposition may apply the pillar material to sidewalls of the first cavity and the second cavity such that the pillar material accumulates inwardly from the sidewalls until the first cavity and the second cavity are filled. The example method may further include planarizing to remove the hard mask layer and pillar material disposed above a pillar height from a surface of the substrate, and removing the semiconductor material to release a first pillar of the pillar material supported by the substrate and a second pillar of the pillar material supported by the substrate.

According to some example embodiments, a nanostructure material is provided. The nanostructure material may include a substrate and a nanostructure pillar disposed on the substrate. The nanostructure pillar may have a pillar width of about 20 nanometers to about 1000 nanometers and an aspect ratio of a pillar height to the pillar width may be within a range from about 10 to 1 to about 4 to 1.

### BRIEF DESCRIPTION OF THE SEVERAL VIEWS OF THE DRAWING(S)

Having thus described some example embodiments in general terms, reference will now be made to the accompanying drawings, which are not necessarily drawn to scale, and wherein:

FIG. 1 illustrates an example nanostructure pillar according to some example embodiments;

FIGS. 2A-2J illustrate states of an example process and method for constructing a nanostructure pillar according to some example embodiments;

FIGS. 3A-3B illustrate states of an example process and for constructing a plurality of nanostructure pillars according to some example embodiments;

FIGS. 4A-4F illustrate example cross-section shapes of a nanostructure pillar according to some example embodiments;

FIG. 5 illustrates an array of nanostructure pillars according to some example embodiments; and

FIG. 6 illustrates a flow chart of an example fabrication method for constructing nanostructure pillars of a nanostructure material according to some example embodiments.

### DETAILED DESCRIPTION

Some example embodiments now will be described more fully hereinafter with reference to the accompanying drawings, in which some, but not all example embodiments are shown. Indeed, the examples described and pictured herein should not be construed as being limiting as to the scope, applicability or configuration of the present disclosure. Rather, these example embodiments are provided so that this disclosure will satisfy applicable legal requirements. Like reference numerals refer to like elements throughout.

In light of the considerations raised above, example methods, and resultant materials, are described herein directed to nanostructure materials including nanostructures with high aspect ratios that are planar and free-standing. In this regard, according to some example embodiments, the aspect ratio of a nanostructure may be defined as the height of the structure relative to the width of the structure. According to some example embodiments, nanostructures as described herein may have different widths depending on where the width measurement is taken, and in these instances, the width used for determining the aspect ratio may be largest width of the nanostructure.

In this regard, example embodiments may facilitate the construction of nanostructures, also referred to as nanostructure pillars or pillars herein, with aspect ratios that are greater than 4 to 1, greater than 6 to 1, and even greater than 10 to 1. In this regard, the nanostructures that make up a nanostructure material may formed as pillars or posts. A nanostructure material may include a substrate with a plurality of nanostructure pillars disposed thereon. The physical attributes of the nanostructure pillars may define the characteristic properties that the nanostructure material exhibits. For example, the height of the nanostructure pillars may have a relationship to the frequencies of electromagnetic radiation or light that the nanostructure material is tuned to act upon. As such, the ability to construct nanostructures with higher aspect ratios enables the ability to tune the nanostructure material to a greater range of frequencies making additional applications accessible.

As mentioned above, the nanostructure materials that may be formed via the example methods described herein may be used in various applications including, for example, meta-lenses and meta-optics. The nanostructure pillars constructed via the example methods provided herein may be sized to have a subwavelength height (e.g., a multiple of the target wavelength), which facilitates use in meta-lens and metasurface applications. For example, the heights of pillars may contribute to defining a focal length of a meta-lens constructed using the pillars. In this regard, an array of nanostructure pillars may be formed, according to some example embodiments, that can operate as a meta-lens or other type of meta-material. As such, example embodiments may have applications in the augmented reality/virtual reality space, solar cell space, electro-optical sensors, infrared sensors, medical imaging, optical communications, light detection and ranging (LiDAR), vision therapeutics, taggants, power generation, and energy harvesting applications, to name a few.

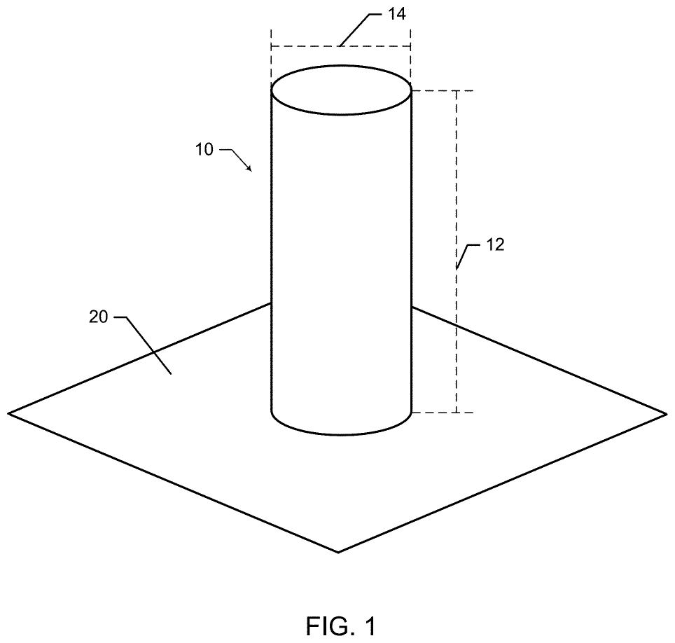

Referring to FIG. 1, an example illustration of a single structure in the form of a pillar 10 is shown, according to some example embodiments. The pillar 10 may be one of a plurality of nanostructure pillars that make up an array of nanostructure pillars of a nanostructure material, according to some example embodiments.

In this regard, the pillar 10 may be disposed on a substrate 20. The pillar 10 may be formed of, for example, a dielectric material, such as titanium dioxide (TiO₂), zinc dioxide (ZnO₂), hafnium dioxide (HfO₂), or the like. The substrate 20 may be a formed of a dielectric material or a semiconductor material. As a dielectric material, the substrate 20 may be, for example, quartz. However, as a semiconductor material, the substrate 20 may be a silicon-based material or other material that exhibits semiconductor properties.

As further described below, example embodiments of nanostructure pillars may be constructed having a variety of different cross-sectional geometries. In the example embodiment shown in FIG. 1, the pillar 10 is shown as having a cylinder shape. As such, the pillar 10 of FIG. 1 has a circular cross-section (taken parallel to the surface of the substrate 20).

As mentioned above, a nanostructure pillar, such as the pillar 10, may have an aspect ratio that is defined by the height 12 of the pillar 10 relative to the width 14 of the pillar 10. The height 12 of the pillar 10 may be the distance from the interface between the pillar 10 and the substrate 20 at the pillar 10's base and the top surface of the pillar 10, opposite the interface with the substrate 20. The width 14 of the pillar 10 may be a distance across the top surface of the pillar 10 or across a cross-section of the pillar 10 that is measured parallel to the surface of the substrate 20, which in the example embodiment of FIG. 1 is planar. Since pillar 10 has a circular cross-section, the width 14 of the pillar 10 is the diameter of the circular cross-section. However, it is understood that pillar 10 may have a different architecture according to some example embodiments, and therefore the width 14 may be, for example, a longest measurement across the top surface or cross-section of the pillar 10.

As mentioned above, the dimensions of the pillar 10 may be on the nanometer scale. In this regard, for example, the width 14, according to some example embodiments, may be from about 20 nanometers (nm) to about 1000 nm. The height of the pillar 10, according to some example embodiments, may be between about 100 nm and about 4000 nm. Further, with respect to aspect ratio, the pillar 10 may, according to some example embodiments, have an aspect ratio of greater than 4 to 1. Alternatively, according to some example embodiments, the pillar 10 may have an aspect ratio of greater than 6 to 1. Alternatively, according to some example embodiments, the pillar 10 may have an aspect ratio of about 10 to 1. Accordingly, example dimensions for the pillar 10 may be a height 12 of 1000 nm and a width 14 of 100 nm (i.e., a 10 to 1 aspect ratio).

As further described below, the pillar 10 may be formed within a cavity that is filled via an atomic layer deposition (ALD) process. However, in example embodiments where the cavity is formed via an etching process, the base of the cavity may be rounded. As such, the base of the pillar 10 at the interface with the substrate may be rounded or tapered toward a center axis of the pillar 10, where the center axis is perpendicular to the surface of the substrate.

As such, using the example methods described herein, a nanostructure material may be constructed that includes a substrate and a nanostructure pillar disposed on the substrate, where the nanostructure pillar has a pillar width of about 20 nanometers to about 1000 nanometers. Further, the nanostructure pillar may have an aspect ratio of a pillar height to the pillar width that is within a range from about 10 to 1 to about 4 to 1. According to some example embodiments, nanostructure pillars may be constructed that have an aspect ratio of up about 20 to 1. The nanostructure pillar may be one of a plurality of nanostructure pillars making up a nanostructure array. The nanostructure pillars within the example array may have different geometries (e.g., cross-sectional shapes), but may be planar with respect to height. According to some example embodiments, the nanostructure pillars may be formed of dielectric materials including, for example, titanium, zinc, hafnium, or the like, such as titanium oxide, zinc oxide, hafnium oxide or the like.

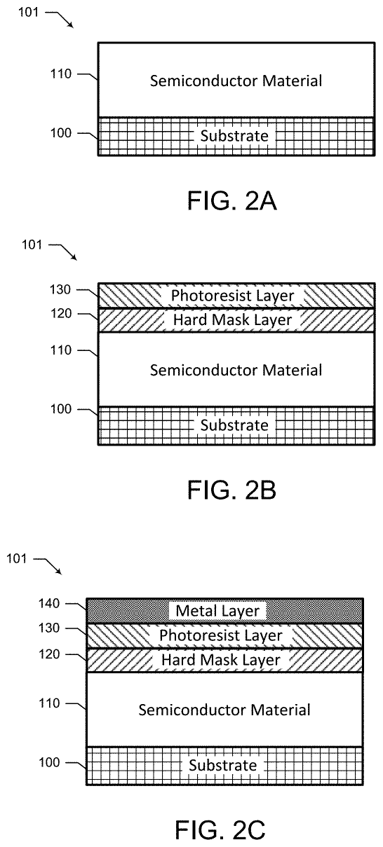

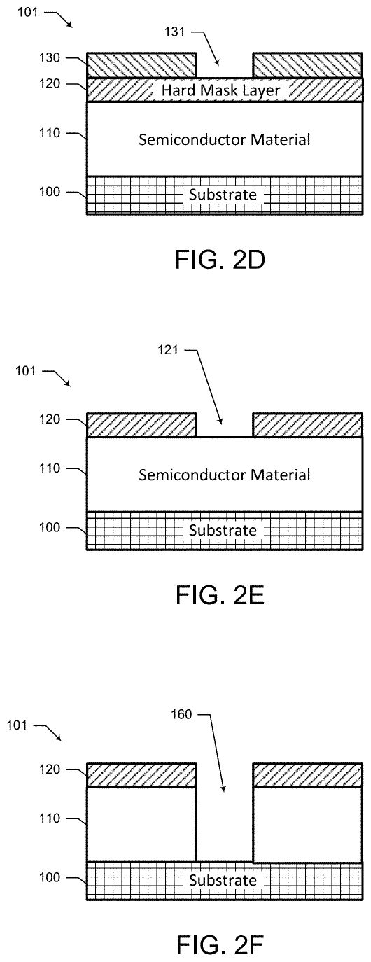

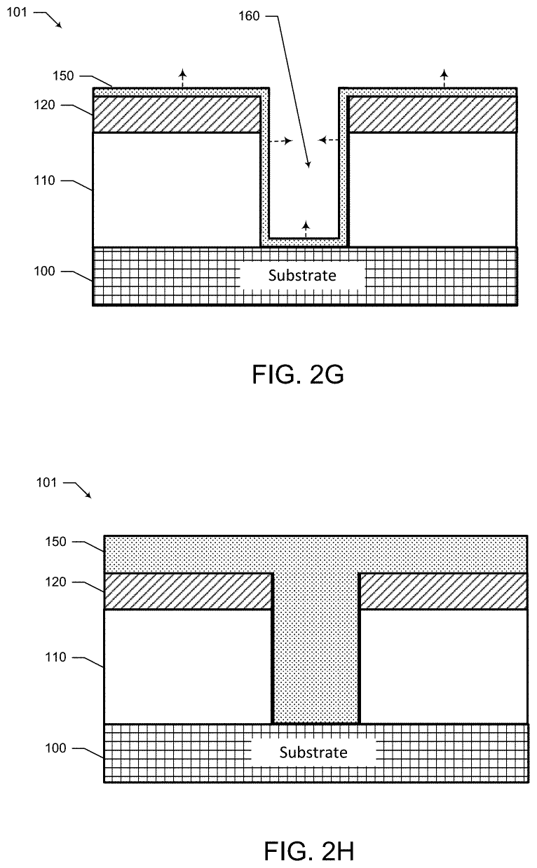

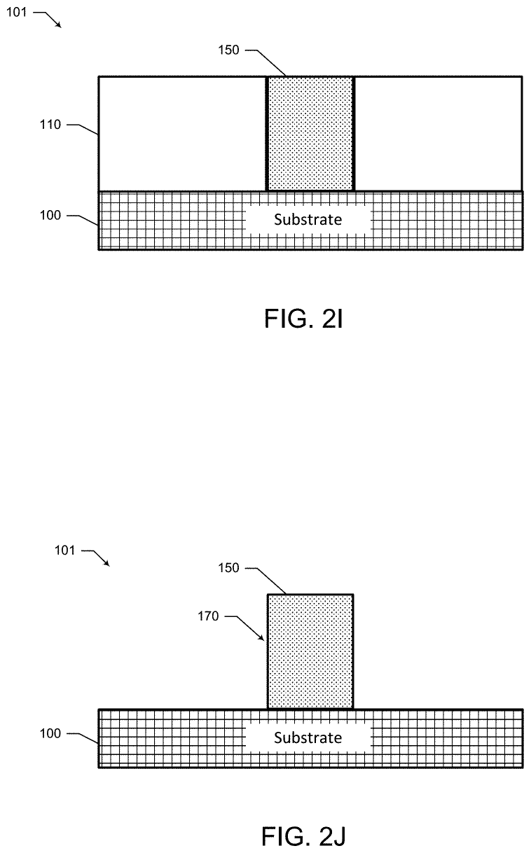

FIGS. 2A-2J will now be described, which illustrate some example fabrication methods for constructing one or a plurality of nanostructure pillars according to some example embodiments of use in constructing a nanostructure material. While FIGS. 2A-2J illustrate the construction of a single nanostructure pillar, it is understood that the same or similar methods may be used to construct a plurality of nanostructure pillars that may be part of an array based on a desired pattern for a nanostructure material. Additionally, it is also understood that the operations or steps that result in a high aspect ratio nanostructure pillar, according to some example embodiments, may differ from those described below while achieving the same outcome.

Referring now to FIG. 2A, the example fabrication process may begin with a construct 101 by depositing a semiconductor material 110 onto a substrate 100. According to some example embodiments, the substrate 100 may be formed, in the same or similar manner as substrate 20, as a semiconductor material or a dielectric material. As a dielectric material, the substrate 100 may be, for example, quartz. However, as a semiconductor material, the substrate 100 may be a silicon-based material that exhibits semiconductor properties. The substrate 100 may be wafer upon which the fabrication processes may be performed to construct a nanostructure pillar and a nanostructure material.

According to some example embodiments, the semiconductor material 110 may be silicon-based or other semiconductor material that exhibits semiconductor properties. According to some example embodiments, the semiconductor material 110 may be amorphous silicon. Further, the process for depositing the semiconductor material 110 on the substrate 100 may include plasma enhanced vapor deposition (PECVD). Alternatively, the semiconductor material 110 may be applied via evaporation using an electron beam, or another deposition process may be used. Further, the height of the semiconductor material 110 (e.g., height above the substrate 100 to a top surface of the semiconductor material 110) may be selected to be larger than the desired pillar height that is being constructed to allow for subsequent planarizing to the desired height as described below.

Referring now to FIG. 2B, additional layers may be applied to the semiconductor material 110. In this regard, according to some example embodiments, a hard mask layer 120 may be applied on the semiconductor material 110. The hard mask layer 120 may constructed for deep etching a cavity in semiconductor material 110 as further described below. The hard mask layer 120 may be, for example, evaporated onto the semiconductor material 110. According to some example embodiments, the hard mask layer 120 may include a metal, such as aluminum. In this regard, for example, the hard mask layer 120 may be formed of alumina or Al₂O₃. Other examples of materials for use to form the hard mask layer may include materials including nickel, other aluminum composites, or the like. Via evaporation or another process, the hard mask layer 120 may be applied across the entire top surface of the semiconductor material 110.

On the hard mask layer 120, according to some example embodiments, a photoresist layer 130 may be applied. Similar to the hard mask layer 120, the photoresist layer 130 may be applied across an entire top surface of the hard mask layer 120. In this regard, the material of the photoresist may be applied as a layer 130 via, for example, a spin and bake process. According to some example embodiments, the photoresist material may be an electron beam (e-beam) photoresist material. According to some example embodiments, the photoresist layer 130 may be applied with patterning using, for example, techniques including nano-imprinting and double patterning lithography (DLP) resulting in a patterned photoresist layer 130 as shown in FIG. 2D.

Alternatively, to pattern the photoresist layer 130, a metal layer 140 may be applied to the photoresist layer 130, as shown in FIG. 2C. According to some example embodiments, the metal layer 140 may be included when the substrate 100 is a dielectric, but may be omitted when the substrate 100 is a semiconductor material. In this regard, the metal layer 140 may be thin relative to, for example, the hard mask layer 120. The metal layer 140 may be added on the photoresist layer 130 to facilitate subsequent electron-beam (e-beam) lithography. According to some example embodiments, the metal layer 140 may be formed of gold (Au). The metal layer 140 may be applied via evaporation or the like, such that the metal layer 140 is applied across, in some example embodiments, the entire top surface of the photoresist layer 130.

As shown in FIG. 2D, lithography may be performed to pattern (e.g., nano-pattern) the photoresist layer 130. In this regard, according to some example embodiments, the photoresist layer 130 may be acted upon to form voids at desired locations for patterning the photoresist layer 130. Such voids are introduced with desired shapes that will be the cross-sectional shapes of the resulting nanostructure pillars. According to some example embodiments, when the metal layer 140 is included, e-beam lithography (EBL) may be performed, which may operate to form the voids in the photoresist layer 130 at desired locations while consuming the metal layer 140. In example embodiments that do not include the metal layer 140, lithography, such as e-beam lithography may be performed directly on the photoresist layer 130, due to the substrate 100 being a semiconductor material.

According to some example embodiments, other lithography approaches may be used that, for example, do not require a hard mask layer. For example, laser or stepper lithography may be used to form the voids photoresist layer 130 for patterning. In some example embodiments, since the hard mask layer is not included, the photoresist layer 130 may operate as the mask to form the cavities in the semiconductor material 110.

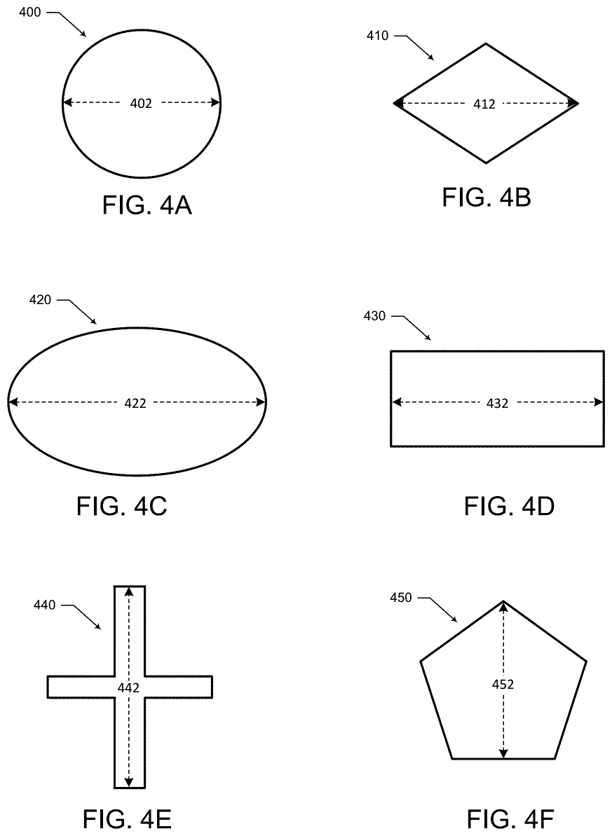

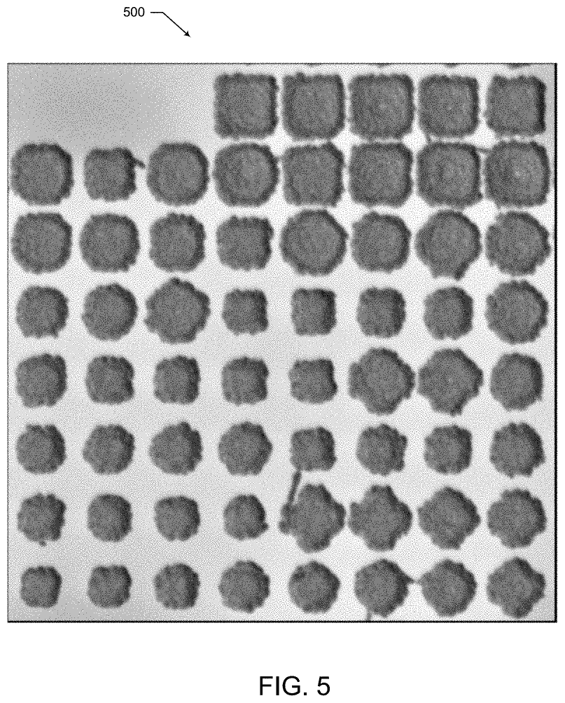

The lithography that is performed may be conducted in a manner that facilitates the patterning of various cross-sectional shapes for the nanostructure pillars, as further described with respect to FIGS. 4A-4F below. In this regard, while the structure shown in FIG. 2D shows a single void, it is understood that the patterning may be performed to form a plurality of voids of desired shapes and locations to facilitate the ultimate formation of an array of nanostructures for a nanostructure material on the substrate 100. As mentioned above, rather than using e-beam lithography to pattern the photoresist layer 130, nano-imprinting using double patterning lithography (DLP) or the like may be utilized according to some example embodiments.

Now referring to FIG. 2E, patterning of the hard mask layer 120 may be performed. In this regard, using the patterned photoresist layer 130 as a guide, the hard mask layer 120 may be similarly patterned to form corresponding voids 121 in the hard mask layer 120. To do so, according to some example embodiments, ion milling may be used to form the patterned voids in the hard mask layer 120, thereby exposing the semiconductor material 110 at the locations of the patterned voids 121, having the desired cross-sectional shapes. According to some example embodiments, rather than using ion milling to pattern the hard mask layer 120, etching may alternatively be performed to introduce the patterning and associated voids into the hard mask layer 120.

In some example embodiments, the hard mask layer 120 may be alternately formed via a lift off process. In this regard, a negatively polarized photoresist layer 130 may be used and the patterning of the photoresist layer 130 may be inverted (relative to the description above) such that the photoresist layer 130 remains in locations where the hard mask layer 130 is to be removed (rather than preserved). As such, the hard mask layer 120 is applied over top of the patterned photoresist layer 130. In such example embodiments, the photoresist layer 130, after patterning, may be disposed in areas where the hard mask layer 120 that will be lifted off (e.g., at the location on the semiconductor material 110 where the cavity 160 is to be formed. After patterning the photoresist layer 130, the hard mask layer 120 may be applied such that the portion of the hard mask layer 120 to be lifted off will be disposed on the patterned photoresist layer 130 and the portion of the hard mask layer 120 to remain will be disposed directly on the semiconductor material 110. The lift off process may be performed using laser or stepper lithography to remove the patterned photoresist layer 130 and the portion of the hard mask layer 120 that is disposed on the patterned photoresist layer 130 to arrive at a hard mask layer 120 as shown in FIG. 2E.

With the hard mask layer 120 patterned, etching of the semiconductor material 110 may be performed as shown in FIG. 2F. The semiconductor material 110 may be etched to have cavities 160 or nanoholes that correspond to the voids in the hard mask layer 120. The cavities 160 will later be filled to the form the nanostructure pillars. Various types of etching may be performed to form the cavities 160. For example, inductively coupled plasma—reactive ion etching (ICP-RIE) may be performed. According to some example embodiments, deep reactive ion etching (DRIE) may be performed, using a highly anisotropic and smooth etch profile. In this regard, for example, the Bosch process using etching or passivation cycles. Alternatively, instead of the Bosch process, a right mix ratio etch of (e.g., SF₆) and passivation (e.g., C₄F₈) may be used together to etch the pattern. As a result of the etching process, according to some example embodiments, the photoresist layer 130 may be consumed.

Since the cavities 160 will be used to form the nanostructure pillars, the cavities 160 may be formed as molds for the nanostructure pillars. In this regard, the width of the cavity 160 may be same as the desired width of the nanostructure pillar and the depth of the cavity 160 may be larger than the desired height of the nanostructure pillar to achieve the desired aspect ratio for the nanostructure pillar. In this regard, the width of the cavity 160 may be 20 nm to 1000 nm, according to some example embodiments. Further, since the top portion of the structure will be later cut or planarized, the depth of the cavity 160 may be greater than the desired height of the nanostructure pillars, according to some example embodiments. Additionally, because the etching process may not be capable of creating right-angle interfaces at the base of the cavity 160 (i.e., at the interface between the cavity 160 and the substrate 100), the cavity 160 may be slightly tapered or curved at the base, which may cause the nanostructure pillars to have slightly tapered or curved edges.

Now referring to FIG. 2G, an atomic layer deposition (ALD) process may be begun to fill the cavity 160. The ALD process may initially introduce pillar material 150 as a conformal layer that covers the top and sidewall surfaces of the structure, as shown in FIG. 2G. As indicated by the arrows, the ALD process will increase the thickness of the pillar material 150 over time. As such, growth of the pillar material 150 within the cavity 160 will extend towards the center of the cavity 160 from the sidewalls and the base of the cavity. In this regard, since ALD can require lengthy periods for time to grow the layers, example embodiments result in a relatively faster process because the growth occurs from the sidewalls to meet at the center, relative to a solution that might grow only from the base upwards. As such, the ALD process involving the cavity 160, as described herein, can be completed in a much shorter period of time due to the converging growth of the pillar material 150 within the cavity 160 from sidewalls of the cavity 160 such that the pillar material 150 accumulates inwardly from the sidewalls until the cavity is filled. As shown in FIG. 2H, when the ALD process is complete, the cavity 160 is filled with the pillar material 150 and a layer of the pillar material 150 is also disposed across the top surface of the construct as a conformal layer.

According to some example embodiments, the pillar material 150 may be any type of material that may be deposited using ALD. According to some example embodiments, the pillar material 150 may be a dielectric material having a desired dielectric value for the nanostructure material application. For example, according to some example embodiments, the pillar material 150 may include a metal such as titanium, zinc, hafnium, or the like. In this regard, the pillar material 150 may be titanium dioxide (TiO₂), zinc dioxide (ZnO₂), hafnium dioxide (HfO₂), or the like.

With the cavity 160 filled with the pillar material 150, planarization may be performed as shown in FIG. 2I. In this regard, planarization may be performed to cut the upper portion of the construct away such that only the semiconductor material 110 and the pillar material 150 within the cavity 160 remain. As such, planarization may remove at least the hard mask layer 120 and the layer of pillar material 150 above the cavity 160 from the construct 101. According to some example embodiments, the planarization may be performed to define the height of the nanostructure pillar to be formed. As mentioned above, the cavity 160 may have a depth that is greater than the desired pillar height to facilitate a clean planarization to be performed to generate one or more pillars at the desired height (e.g., height 12) and an associated desired aspect ratio. According to some example embodiments, planarization may be performed in a number of different ways, such as, for example, ion milling, plasma etching, reactive ion etching, chemical mechanical polishing (CMP), or the like.

Now referring to FIG. 2J, the semiconductor material 110 may be removed to release the pillar 170 that is now self-supported on the substrate. In this regard, the pillar 170 may be the same or similar to the pillar 10 described above. The semiconductor material 110 may be removed in a variety of different ways, such as being dissolved or otherwise reacted with to be removed. For example, according to some example embodiments, a fluorinating agent such as, for example, xenon difluoride (XeF₂) for amorphous silicon or silicon, may be applied as a dry etch to release the semiconductor material 110 and allow the pillar 170 of pillar material 150 to remain. Other etching or removal techniques may also be used to remove the semiconductor material 110. The resultant nanostructure pillar 170 may have physical characteristics similar to or the same as those described with respect to pillar 10 described above. According to some example embodiments, the pillar 170 formed according to some example embodiments, may have an aspect ratio that could not be achieved via direct etching of the pillar material 150 to remove material and form the pillar.

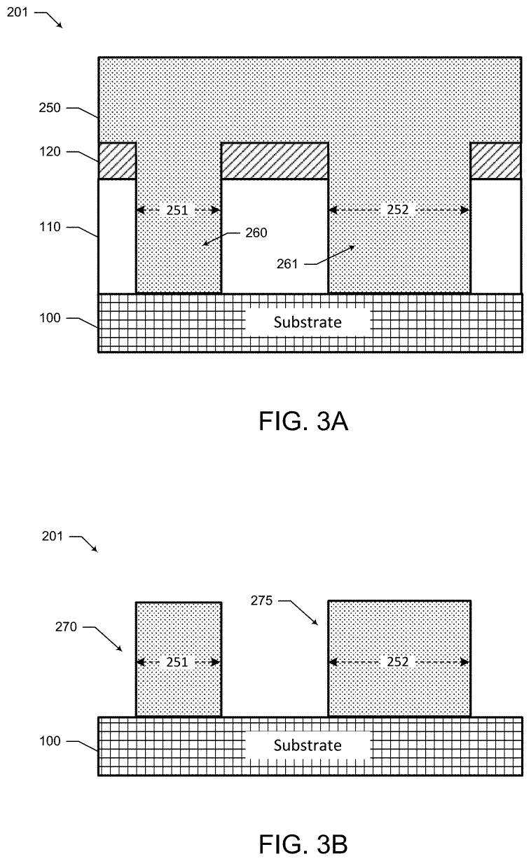

As mentioned above, it is understood that the pillar 170 is described as being a singular pillar on the substrate 100, but any number of pillars may be formed with the pillar 170 in a similar manner. FIGS. 3A and 3B illustrate an example construct formed, according to some example embodiments, to have nanostructure pillars of differing widths. The process used to arrive at the construct of FIG. 3A may be the similar to process described with respect to the process of FIGS. 2A-2J, however with patterning that creates nanostructure pillars of different widths.

As can be seen in FIG. 3A, ALD has been performed to fill cavities 260 and 261 with pillar material 250. The pillar material 250 may be the same or similar to the pillar material 150. However, it can be seen in FIG. 3A, that the width 251 of cavity 260 is smaller than the width 252 of cavity 260. As such, the pillars formed by these cavities 260 and 261 will have different aspect ratios due to their differing widths. Further, it is noted that ALD was used to the fill the cavities 260 and 261, the conformal layer that is formed has a constant height across the construct 201, despite the fact that the cavities are different widths, and, accordingly, cavity 260 was filed prior to cavity 261 being filled.

As such, referring to FIG. 3B, planarization can still be performed, as described with respect to FIG. 2I. Since the upper surface of the construct of FIG. 3A is still uniform, planarization can still be performed without concern for variations in thickness due to cavities of differing sizes. Accordingly, planarization and can be performed and the semiconductor material 110 can be released in the same manner as described above. As such, the result of a first nanostructure pillar 270 with a width 251 and a second nanostructure pillar 275 with a width 252 that is larger than the width 251 can be realized on the substrate 100.

Having described various methods for constructing a nanostructure pillar, FIGS. 4A-4F illustrate some example embodiments of cross-sections of example nanostructure pillars according to some example embodiments. In this regard, the accuracy of the etching that may be used to form the cavities that are used as molds for forming the pillars may offer the ability to construct pillars having various different cross-sectional shapes including rounded shapes and polygon shapes. In this regard, FIG. 4A illustrates an example embodiment where the cross-section 400 of the pillar is a circle with a width 402. FIG. 4B illustrates an example embodiment where the cross-section 410 of the pillar is a diamond or parallelogram shape with a width 412. FIG. 4C illustrates an example embodiment where the cross-section 420 of the pillar is an oval shape with a width 422. FIG. 4D illustrates an example embodiment where the cross-section 430 of the pillar is a rectangular shape with a width 432. FIG. 4E illustrates an example embodiment where the cross-section 440 of the pillar is a cross shape with a width 442. FIG. 4F illustrates an example embodiment where the cross-section 450 of the pillar is a pentagon shape with a width 452.

Referring to FIG. 5, an image of an array 500 of nanostructures in the form of nanostructure pillars is shown according to some example embodiments. The array 500 includes a plurality of nanostructure pillars assembled and spaced in a matrix-type configuration. Additionally, as can be seen in FIG. 5, the nanostructure pillars have different cross-sectional shapes including squares and circles with different widths, and therefore different aspect ratios.

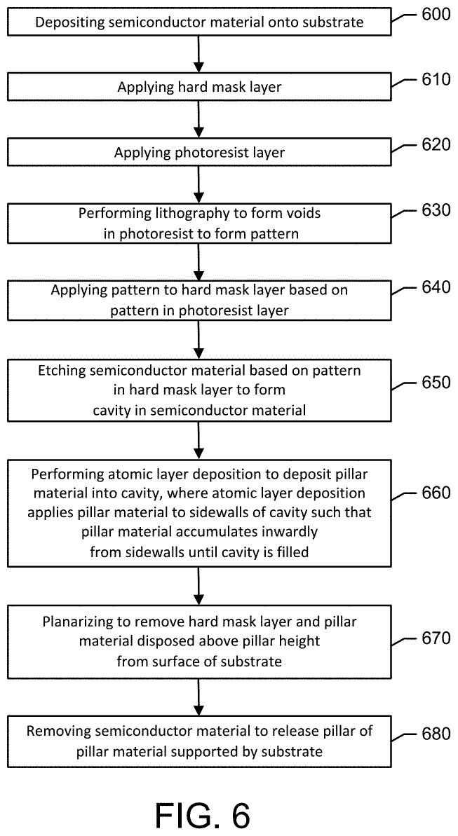

Now referring to FIG. 6, a fabrication process and method is described for constructing structures, including nanomaterial structures, according to some example embodiments. In this regard, the example method may include, at 600, depositing a semiconductor material onto a substrate. At 610, the example method may include applying hard mask layer, according to some example embodiments, onto the semiconductor material, and, at 620, applying a photoresist layer, according to some example embodiments, onto the hard mask layer. At 630, the example method may include performing lithography to form voids in the photoresist layer that form a pattern in the photoresist layer.

According to some example embodiments, the ordering of operations 610, 620, and 630 may be different to perform a lift off variation of the example method. In this regard, at 620, the photoresist layer may be first applied to the semiconductor material. Then, at 630, patterning of the photoresist layer may be performed, followed by application of the hard mask layer onto the patterned photoresist layer in preparation for lifting off the hard mask layer.

The example method may also include, at 640, applying the pattern to the hard mask layer based on the pattern in the photoresist layer to form the pattern in the hard mask layer. Subsequently, at 650, the pattern in the hard mask layer may be used for etching the semiconductor material to form a cavity in the semiconductor material.

According to some example embodiments, the example method may further include, at 660, performing atomic layer deposition to deposit pillar material into the cavity. In this regard, the atomic layer deposition may apply the pillar material to sidewalls of the cavity such that the pillar material accumulates inwardly from the sidewalls until the cavity is filled. Additionally, at 670, the example method may include planarizing to remove the hard mask layer and pillar material disposed above a pillar height from a surface of the substrate. The example method may also include removing the semiconductor material to release a pillar of the pillar material supported by the substrate.

According to some example embodiments, the example method may additionally, include applying a conductive layer to the photoresist layer prior to performing the lithography. In this regard, the performing the lithography may include performing electron beam lithography to form the pattern in the photoresist layer and remove the conductive layer. Additionally or alternatively, the semiconductor material may include silicon, according to some example embodiments. Additionally or alternatively, according to some example embodiments, the hard mask layer may include Aluminum, such as, for example aluminum oxide.

Additionally or alternatively, accordingly to some example embodiments, applying the pattern to the hard mask layer includes ion milling the hard mask layer. Additionally or alternatively, according to some example embodiments, planarizing includes ion milling or plasma etching. Additionally or alternatively, according to some example embodiments, the pillar material may include titanium, zinc, hafnium, or the like. Additionally or alternatively, an aspect ratio of the pillar may be between 10 to 1 and 4 to 1. Additionally or alternatively, the cross-sectional shape of the pillar may be a polygon.

Additionally or alternatively, the cavity may be a first cavity, and a second cavity may be formed in association with the first cavity in the same manner as the first cavity. Additionally, the first cavity may have a first cross-sectional dimension that is larger than a largest cross-sectional dimension of the second cavity.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. In cases where advantages, benefits or solutions to problems are described herein, it should be appreciated that such advantages, benefits and/or solutions may be applicable to some example embodiments, but not necessarily all example embodiments. Thus, any advantages, benefits or solutions described herein should not be thought of as being critical, required or essential to all embodiments or to that which is claimed herein. Although specific terms are employed herein, they are used in a generic and descriptive sense only and not for purposes of limitation.

What is claimed is:

1. A fabrication method comprising:
depositing a semiconductor material onto a substrate;
applying a hard mask layer;
applying a photoresist layer;
performing lithography to form voids in the photoresist layer that form a pattern;
applying the pattern to the hard mask layer based on the pattern in the photoresist layer;
etching the semiconductor material based on the pattern in the hard mask layer to form a cavity in the semiconductor material;
performing atomic layer deposition to deposit pillar material into the cavity, wherein the atomic layer deposition applies the pillar material to sidewalls of the cavity such that the pillar material accumulates inwardly from the sidewalls until the cavity is filled;
planarizing to remove the hard mask layer and pillar material disposed above a pillar height from a surface of the substrate; and
removing the semiconductor material to release a pillar of the pillar material supported by the substrate.

2. The fabrication method of claim 1, further comprising applying a conductive layer to the photoresist layer prior to performing the lithography, wherein performing the lithography comprises performing electron beam lithography to form the pattern in the photoresist layer and remove the conductive layer.

3. The fabrication method of claim 1, wherein the semiconductor material comprises silicon.

4. The fabrication method of claim 1, wherein the hard mask layer comprises aluminum.

5. The fabrication method of claim 1, wherein applying the pattern to the hard mask layer comprises ion milling the hard mask layer.

6. The fabrication method of claim 1, wherein the planarizing comprises ion milling or plasma etching.

7. The fabrication method of claim 1, wherein the pillar material comprises titanium, zinc, or hafnium.

8. The fabrication method of claim 1, wherein an aspect ratio of the pillar is between 10 to 1 and 4 to 1.

9. The fabrication method of claim 1, wherein a cross-sectional shape of the pillar is a polygon.

10. A fabrication method for a nanostructure material array, the fabrication method comprising:
depositing a semiconductor material onto a substrate;
applying a hard mask layer;
applying a photoresist layer;
performing lithography to form voids in the photoresist layer that form a pattern;
applying the pattern to the hard mask layer based on the pattern in the photoresist layer;
etching the semiconductor material based on the pattern in the hard mask layer to form a plurality of cavities comprising a first cavity in the semiconductor material and a second cavity in the semiconductor material, the first cavity having a first cross-sectional dimension that is larger than a largest cross-sectional dimension of the second cavity;
performing atomic layer deposition to deposit pillar material into the first cavity and the second cavity, wherein the atomic layer deposition applies the pillar material to sidewalls of the first cavity and the second cavity such that the pillar material accumulates inwardly from the sidewalls until the first cavity and the second cavity are filled;
planarizing to remove the hard mask layer and pillar material disposed above a pillar height from a surface of the substrate; and
removing the semiconductor material to release a first pillar of the pillar material supported by the substrate and a second pillar of the pillar material supported by the substrate.

11. The fabrication method of claim 10, wherein
the first pillar has a first aspect ratio of between 4 to 1 and 10 to 1,
the second pillar has a second aspect ratio of between 4 to 1 and 10 to 1, and
the first aspect ratio is different from the second aspect ratio.

12. The fabrication method of claim 10, wherein
the pattern defines a first cross-sectional shape for the first pillar and a second cross-sectional shape for the second pillar, and
the first cross-sectional shape is different than the second cross-sectional shape.

13. The fabrication method of claim 10, wherein heights of the first pillar and the second pillar are the pillar height.

14. The fabrication method of claim 10 further comprising applying a conductive layer to the photoresist layer prior to performing the lithography, wherein the performing the lithography comprises performing electron beam lithography to form the pattern in the photoresist layer and remove the conductive layer.

15. The fabrication method of claim 1, wherein the semiconductor material comprises silicon, the hard mask layer comprises aluminum, and the pillar material comprises titanium, zinc, or hafnium.

16. The fabrication method of claim 1, wherein
the applying the pattern to the hard mask layer comprises ion milling the hard mask layer, and
the planarizing comprises ion milling or plasma etching.

17. A nanostructure material comprising:
a substrate; and
a nanostructure pillar disposed on the substrate, the nanostructure pillar having a pillar width of about 20 nanometers to about 1000 nanometers,
wherein an aspect ratio of a pillar height to the pillar width is from about 10 to 1 to about 4 to 1.

18. The nanostructure material of claim 17, wherein
the nanostructure pillar is a first nanostructure pillar, and
a plurality of nanostructure pillars comprising the first nanostructure pillar are disposed on the substrate as a nanostructure array.

19. The nanostructure material of claim 18, wherein
the plurality of nanostructure pillars comprise the first nanostructure pillar and a second nanostructure pillar, and
the first nanostructure pillar has a different geometry than the second nanostructure pillar.

20. The nanostructure material of claim 17, wherein the nanostructure pillar is formed of materials comprising titanium, zinc, or hafnium.
